(19) United States
(12) Patent Application Publication
(10) Pub. No.: US 2008/0029856 A1
(43) Pub. Date: Feb. 7, 2008

(54) LEADFRAME AND NON-LEAD PACKAGE THEREWITH

(76) Inventors: Chang-Hsu Chou, Kao-Hsiung City (TW); Shu-Yin Chen, Kao-Hsiung City (TW); Chi-Hong Chan, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/620,052

(22) Filed: Jan. 5, 2007

(30) Foreign Application Priority Data
Aug. 4, 2006 (TW) 095128731

(51) Int. Cl. H01L 23/495

(52) U.S. Cl. 257/666

(57) ABSTRACT

The present invention relates to a leadframe and a non-lead package therewith. The non-lead package comprises a leadframe, a die and a molding compound. The leadframe has a frame and a die pad. The frame has a plurality of conducting portions. The frame has a first recess at inner portions of the conducting portions. The die pad has a second recess at the edges of the die. The die is disposed on the die pad. The second recess is formed around the edges of the die pad. By utilizing the second recess, the epoxy-bleeding problem can be improved so as to avoid die pad pollution and irregularity when the die is mounted on the die pad. Furthermore, the non-lead package of the invention does not need a spacer disposed between the die and the die pad. Therefore, the producing processes and cost can be reduced.

### BACKGROUND OF THE INVENTION

1. Field of the Invention

The present invention is related to a leadframe and a package therewith, and more particularly, to a leadframe and a non-lead package therewith.

2. Description of the Prior Art

Referring to FIG. 1, FIG. 1 illustrates a non-lead package 1 in the prior art. The non-lead package 1 includes a leadframe 10, a die 11, a spacer 12, a plurality of conducting elements 13, and a molding compound 14. The leadframe 10 includes a frame 101 and a die pad 102. The frame 101 has a first surface 103 and a plurality of conducting portions 104. The die pad 102 is disposed inside the frame 101 and has a die-located surface 105, which is located on the same plane as the first surface 103. The spacer 12 uses resin as bonding material and is disposed between the die 11 and the die pad 102. The conducting elements 13 are wires electrically connected the die 11 and the conducting portions 104. The molding compound 14 packages the leadframe 10, the conducting elements 13 and the die 11.

Since the die 11 of the conventional non-lead package 1 has a larger size than the die pad 102, the spacer 12 is required to prevent the die 11 from contacting with the conducting portions 104. The spacer 12 uses resin as bonding material and is disposed between the die 11 and the die pad 102. However, the die pad has no apparatus to suppress resin bleeding. The resin overflows onto the sidewall and the bottom of the die pad 102, which results in pollution and an irregularity when the die 11 is mounted on the die pad. Moreover, the conventional non-lead package 1 requires the spacer 12 to be disposed between the die 11 and the die pad 102, which increases the steps of packaging and the cost of production. Consequently, a creative and progressive leadframe and a non-lead package therewith are required to resolve the above-mentioned problems.

### SUMMARY OF THE INVENTION

The primary objective of the present invention is to provide a leadframe. The leadframe includes a frame and a die pad. The frame has a first surface and a plurality of conducting portions, and the conducting portions has a first recess at inner portions thereof. The die pad is disposed inside the frame, and has a die-located surface and a second recess. In addition, the die-located surface and the first surface of the frame are located on the same plane. The second recess is formed around the die-located surface and the die pad.

Further, another objective of the present invention is to provide a non-lead package. The non-lead package has a leadframe, a die, and a molding compound. The leadframe includes a frame and a die pad. The frame has a first surface and a plurality of conducting portions. The conducting portions include a first recess at inner portions of the conducting portions. The die pad is disposed inside the frame, and the die pad has a die-located surface and a second recess. Moreover, the die-located surface and the first surface are located on the same plane, and the second recess is disposed around the die pad. The die is disposed on the die-located surface, and the edge of the die is disposed above the first recess. Additionally, the molding compound packages the leadframe and the die.

The die pad of the present invention has the second recess. When a die is bonded to the die-located surface by the resin, the overflowed resin will be halted at the second recess without bleeding on the sidewall or the bottom of the die pad. Therefore, problems of pollution and irregularity when the die is mounted on the die pad resulted from conventional technique will be solved. The conducting portions have the first recess, and the edges of the die may be extended to the regions above the first recess. Hence, other die have bigger size may be packaged in the non-lead package of the present invention. Moreover, the non-lead package of the present invention does not require the spacer used in the traditional packages that reduces the steps of packaging and cost of production.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a package in prior art.

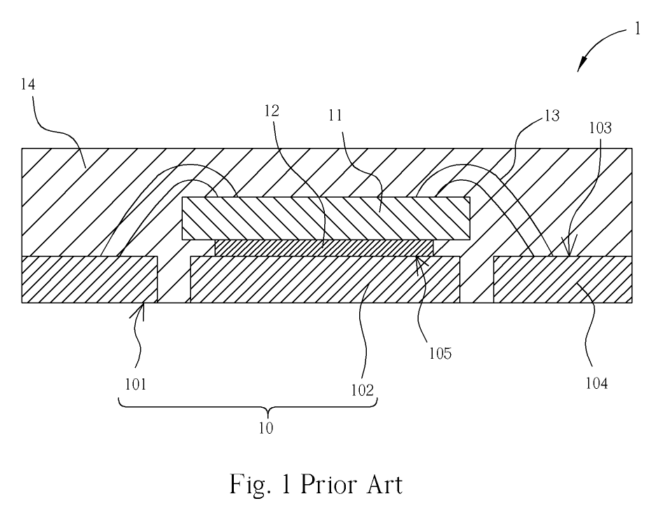

FIG. 2 illustrates a leadframe according to a first embodiment of the present invention.

FIG. 3 illustrates another leadframe according to a second embodiment of the present invention.

FIG. 4 illustrates a non-lead package according to the first embodiment of the present invention.

FIG. 5 illustrates another non-lead package according to the second embodiment of the present invention.

### DETAILED DESCRIPTION

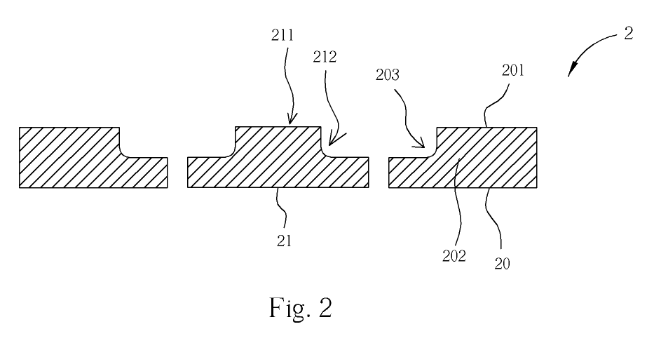

Referring to FIG. 2, FIG. 2 illustrates a leadframe 2 according to a first embodiment of the present invention. The leadframe 2 of the present invention includes a frame 20 and a die pad 21. The frame 20 has a first surface 201 and a plurality of conducting portions 202. The inner portions of the conducting portions 202 have a first recess 203. And, the first recess 203 has a cambered surface. In the first embodiment, the leadframe 2 is for quad flat non-lead (QFN) package. In addition, the leadframe 2 may be used for dual flat non-lead (DFN) package in other applications.

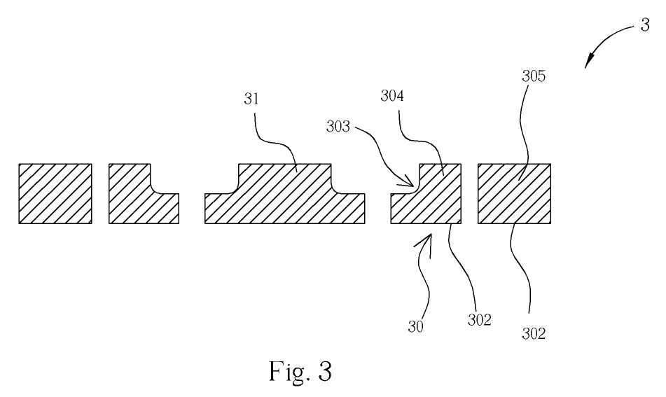

The die-pad 21 is located inside the frame 20, and has a die-located surface 211 and a second recess 212. The second recess 212 has a cambered surface. The die-located surface 211 and the first surface 201 of the frame 20 are located on the same plane. The second recess 212 is disposed around the die-pad 21. In the first embodiment, the first recess 203 and the second recess 212 are formed by etching. Therefore, the outline of the conducting portions 202 and the die pad 21 has a smaller top than the bottom thereof. Preferably, the second recess 212 is formed around the die-located surface 211. Please refer to FIG. 3. FIG. 3 illustrates another leadframe 3 according to a second embodiment of the present invention. The leadframe 3 has a frame 30 and a die pad 31. The differences between the lead frame 3 and the lead frame 2 of the first embodiment shown in FIG. 2 is that the conducting portions 302 of the lead frame 3 has a plurality of inner conducting portions 304 and a plurality of outer conducting portions 305. The inner conducting portions 304 and the outer conducting portions 305 are located a predetermined distance, d, from each other. The inner conducting portions 304 has a first recess 303a the inner portions thereof.

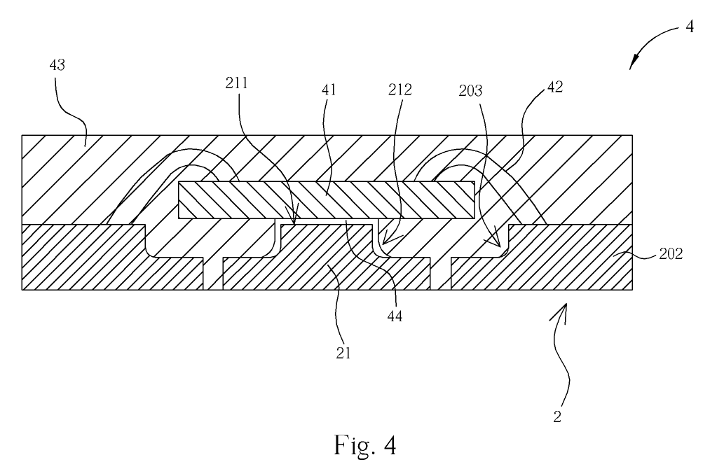

Referring to FIG. 4, FIG. 4 illustrates a non-lead package 4 according to the first embodiment of the present invention. The non-lead package 4 has the leadframe 2 of the present invention shown in FIG. 2, a die 41, a plurality of conducting elements 42, and a molding compound 43. An adhesive layer 44, such as resin, is disposed between the die 41 and the die pad 21. The adhesive layer 44 bonds the die 41 to the die-located surface 211, and the adhesive layer 44 covers a part of the second recess 212 of the die pad 21. The edges of the die 41 are located correspondingly above the first recess 203 without contacting the conducting portions 202. In addition, a projection area of the die pad 21 is smaller than a projection area of the die 41. And then, the molding compound 43 is utilized to package the leadframe 2, the die 41, and the conducting elements 42. The non-lead packages 4 may be utilized as a quad flat non-lead package or a dual flat non-lead package.

The die pad 21 of the present invention has the second recess 212. When the die 41 is bonded to the die-located surface 211 by the resin, the overflowed resin will be halted at the second recess 212 without bleeding to the sidewall or the bottom of the die pad 21. Therefore, problems of pollution and irregularity when the die is mounted on the die pad resulted from the conventional technique will be solved. The conducting portions 202 have the first recess 203, and the edges of the die 41 may be extended to the regions above the first recess 203. Hence, other die having bigger size may be packaged in the non-lead package 4 of the present invention. Moreover, the non-lead package 4 of the present invention does not require the spacer used in the traditional packages that reduces the steps of packaging and cost of production.

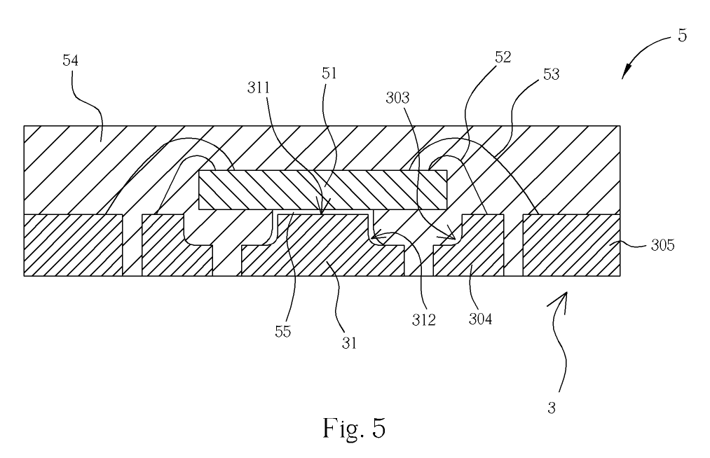

Referring to FIG. 5, FIG. 5 illustrates another non-lead package 5 according to the second embodiment of the present invention. The package 5 includes the leadframe 3 of the second embodiment shown in FIG. 3, a die 51, a plurality of conducting elements 52, 53, and a molding compound 54. An adhesive layer 55, such as resin, is disposed between the die 51 and the die pad 31. The adhesive layer 55 bonds the die 51 to the die-located surface 311, and the adhesive layer 55 covers a part of the second recess 312 of the die pad 31. The edges of the die 51 are located correspondingly above the first recess 303 without contacting the inner conducting portions 304. In addition, a projection area of the die pad 31 is smaller than a projection area of the die 51.

The die 51 is electrically connected to the inner conducting portions 304 and the outer conducting portions 305 by the conducting elements 52, 53. And then, the molding compound 54 is used to package the leadframe 3, the die 51, and the conducting elements 52, 53. The non-lead package 5 may be utilized as a quad flat non-lead package or a dual flat non-lead package. The non-lead package 5 not only has the advantages of the non-lead package 4, but also has more connections with external devices through the inner connecting portions 304 and the outer connecting portions 305.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A leadframe, comprising:
a frame having a first surface and a plurality of conducting portions, the conducting portions having a first recess at inner portions of the conducting portions; and
a die pad disposed inside the frame, the die pad having a die-located surface and a second recess, wherein the die-located surface and the first surface of the frame are located on the same plane and the second recess is disposed around the die pad.

2. The leadframe of claim 1, wherein the leadframe is for quad flat non-lead package.

3. The leadframe of claim 1, wherein the leadframe is for dual flat non-lead package.

4. The leadframe of claim 1, wherein the first recess has a cambered surface.

5. The leadframe of claim 1, wherein the second recess has a cambered surface.

6. The leadframe of claim 1, wherein the first recess and the second recess are formed by etching.

7. The leadframe of claim 1, wherein the second recess is disposed around the die-located surface.

8. The leadframe of claim 1, wherein the conducting portions comprise a plurality of inner conducting portions and a plurality of outer conducting portions located a distance from each other, and the first recess is located at inner portions of the inner conducting portions.

9. A non-lead package, comprising:
a leadframe, comprising:
a frame having a first surface and a plurality of conducting portions, the conducting portions comprising a first recess at inner portions of the conducting portions; and
a die pad disposed inside the frame, the die pad comprising a die-located surface and a second recess, wherein the die-located surface and the first surface are located on the same plane, and the second recess is disposed around the die pad;
a die disposed on the die-located surface, the edge of the die being disposed above the first recess; and
a molding compound packaging the leadframe and the die.

10. The non-lead package of claim 9, wherein the non-lead package is a quad flat non-lead package.

11. The non-lead package of claim 9, wherein the non-lead package is a dual flat non-lead package.

12. The non-lead package of claim 9, wherein the first recess has a cambered surface.

13. The non-lead package of claim 9, wherein the second recess has a cambered surface.

14. The non-lead package of claim 9, wherein a projection area of the die pad is smaller than a projection area of the die.

15. The non-lead package of claim 9, wherein the die is electrically connected to the conducting portions by a plurality of conducting elements.

16. The non-lead package of claim 9, wherein the second recess is disposed around the die-located surface.

17. The non-lead package of claim 9, further comprising an adhesive layer disposed between the die and the die pad.

18. The non-lead package of claim 9, wherein the adhesive layer covers a part of the second recess of the die pad.

19. The non-lead package of claim 9, wherein the conducting portions include a plurality of inner conducting portions and a plurality of outer conducting portions located a distance from each other, and the first recess is located at inner portions of the inner conducting portions.

20. The non-lead package of claim 19, wherein the die is electrically connected to each inner conducting portion and each outer conducting portion by a plurality of conducting elements.
